(19) United States
(12) Patent Application Publication
(10) Pub. No.: US 2008/0083455 A1
(43) Pub. Date: Apr. 10, 2008

(54) Organic photovoltaic cell and manufacturing method therefor

(75) Inventors: Jian Li, Jiangsu (CN); Hiroyuki Fujii, Shiga (JP); Takeshi Sano, Osaka (JP); Kenichirou Wakisaka, Mie (JP)

Correspondence Address: MASUVALLEY & PARTNERS, 8765 AERO DRIVE, SUITE 312, SAN DIEGO, CA, 92123, US

(73) Assignee: Sanyo Electric Co., Ltd., Moriguchi-City (JP)

(21) Appl. No.: 11/891,139

(22) Filed: Aug. 9, 2007

(30) Foreign Application Priority Data
Aug. 10, 2006 (JP) 2006-217686

(51) Int. Cl. H01L 31/00; C08G 75/00

(52) U.S. Cl. 136/263; 528/380

(57) ABSTRACT

The present invention is an organic photovoltaic cell that can be manufactured by using an organic solvent having a low environmental load and high safety, such as xylene, and a manufacturing method therefor. The organic photovoltaic cell according to the present invention has a pair of electrodes and an organic thin film for photoelectric conversion provided between the electrodes, and the organic thin film is formed from an organic material which has a chemical structure of: 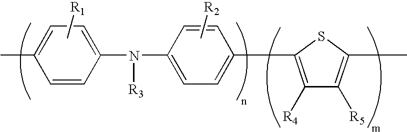
where R₁-R₅ are hydrogen, alkyl group, alkoxy group, or aryl group, and may include oxygen, nitrogen, silicon, phosphorus or sulfur, and wherein and m are counting numbers in the range of 1 to 10000.

### TECHNICAL FIELD

The present invention relates to an organic photovoltaic cell used for solar cells and so on.

### BACKGROUND OF INVENTION

In recent years, the demands for information processing devices, display devices, memory devices that are thin and portable have been increasing with the advanced development of information technology. Also, prepaid type electronic clearing systems, credit type electronic clearing systems, real time type electronic clearing systems, information distribution systems, information exchange systems, and so on using such devices are being developed aiming for practical applications.

Expectation is rising for an organic photovoltaic cell using an organic semiconductor thin film as a technology capable of providing necessary power to operate each of these devices at outdoor use.

The photovoltaic cell using organic thin film is manufactured in a process with a lower temperature compared to an inorganic photovoltaic cell, thereby it can be manufactured in a low cost. Also, plastic or film that is superior in flexibility can be used as a substrate, thus a light weight and durable element can be fabricated. Also, if the element can be fabricated by coating from a solution, spray method, and printing method, a large amount of elements can be manufactured rapidly and at an extremely low cost.

The Published Japanese Translation of PCT application No. 2005-523588 discloses a solar cell provided with a p-type polymer, a n-type electron accepter, and an ionic electrolyte.

As a p-type polymer, each derivative, such as poly(p-phenylene-vinylene) (PPV), polyfluorene (PF), and polythiophene (PT), is disclosed. As the specific manufacturing method of the solar cell, a manufacturing method by spin coating a MEH-PPV: C60 blend (3:1 by weight) from 1,2-dichlorobenzene solution onto indium-tin oxide (ITO) glass substrates which were pre-coated with 80 nm 3,4-polyethylenedioxythiophene-polystyrenesulfonate (PEDOT), is disclosed.

Japanese Unexamined Patent Application No. 2006-49890 discloses a photovoltaic cell wherein a hole transporter or an electron transporter is chemically bonded to an absorber. More specifically, an aromatic amine is disclosed as the hole transporter (p-type polymer).

In the conventional photovoltaic cell described above, the photoelectric conversion efficiency is insufficient due to low carrier mobility, short carrier life, and so on. Also, there is a problem of not being able to fabricate the element in low cost because a film with high evenness is difficult to obtain when fabricating an element by coating from solution, spray method or printing method due to low solubility to the solvent of organic material used, or due to high crystallinity of the material. Also, in the case of using as a solution by dissolving in a solvent, not every solvent is available due to the low solubility of the organic material, for example, polythiophene has to use an organic solvent with a large environmental load containing a halogen element, such as 1-2-dichlorobenzene.

The objective of the present invention is to provide an organic photovoltaic cell with favorable photoelectric conversion characteristics which can be manufactured by using an organic solvent with a low environmental load and high safety, and a manufacturing method therefor.

### BRIEF SUMMARY OF THE INVENTION

The present invention is an organic photovoltaic cell that has a pair of electrodes and an organic thin film provided between the electrodes for photoelectric conversion, and the organic thin film is formed from an organic material that has a chemical structure as shown below.

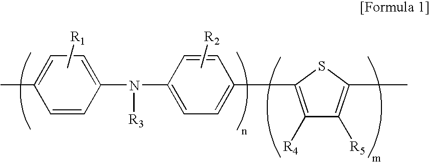

In the formula, R₁-R₅ are a hydrogen, alkyl group, alkoxy group, or aryl group, and may include oxygen, nitrogen, silicon, phosphorus or sulfur. n and m are counting numbers in the range of 1 to 10000.

The present invention is an organic material for manufacturing the organic thin film provided to an organic photovoltaic cell, and the organic material has a structure indicated by the following formula: 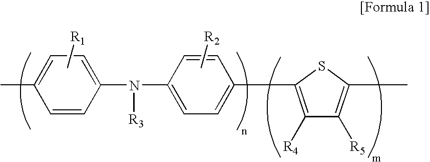
(In the formula, R₁-R₅ are a hydrogen, alkyl group, alkoxy group, or aryl group, and may include oxygen, nitrogen, silicon, phosphorus or sulfur. n and m are counting numbers in the range of 1 to 10000.)

The organic material according to the present invention is a p-type polymer, and the photoelectric conversion efficiency can be improved by using this. The reason for this is thought to be because the organic material according to the present invention has a high carrier mobility or a high carrier life.

Also, the organic material according to the present invention has a high solubility to organic solvents, thereby the organic thin film may be formed by coating from solution, spay methods, and printing methods, which allows the manufacture of the organic photovoltaic cell at a low cost.

Also, since the organic solvents with a low environmental load and high safety, such as xylene, can be used to manufacture, the organic photovoltaic cell is preferable with regard to environmental health.

R₁-R₅ in the above general formula may be an alkyl group or alkoxy group as described above. The number of carbons in this case is preferably in the range of 2-20. Also, R₁-R₅ may be an aryl group such as a phenyl group or naphthyl. In this case, the number of carbons is preferably in the range of 3-20. R₁-R₅ may include other elements, such as oxygen, nitrogen, silicon, phosphorus or sulfur.

n is a counting number in the rage of 1-10000, preferably, 30-900, and more preferably 90-300.

m is a counting number in the rage of 1-20000, preferably, 30-1800, and more preferably 90-600.

The organic material according to the present invention preferably has the following chemical structure.

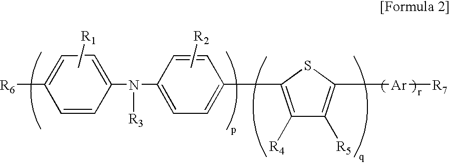

In the formula, Ar is an aryl group, R₁-R₇ are a hydrogen, alkyl group, alkoxy group, or aryl group, and may include oxygen, nitrogen, silicon, phosphorus or sulfur. p is a counting number in the range of 1 to 10000, q is a counting number in the range of 1-20000, and r is an integral number in the range of 0 to 10000)

Ar in the general formula above is an aryl group and aromatic family group or a condensed-ring compound, such as benzene, naphthalene, anthracene, tetracene, pentacene, fluorene, or carbazole can be considered. These may have substituents. Also, R₁-R₇ are the similar substituent as R₁-R₅ above.

x is a counting number in the rage of 1-10000, preferably, 30-900, and more preferably 90-300.

y is a counting number in a range of 1-20000, preferably, 30-1800, further preferably, 90-600

z is a integral number in the rage of 1-10000, preferably, 30-900, and more preferably 90-300.

Below are more specific compounds for the organic material according to the present invention:

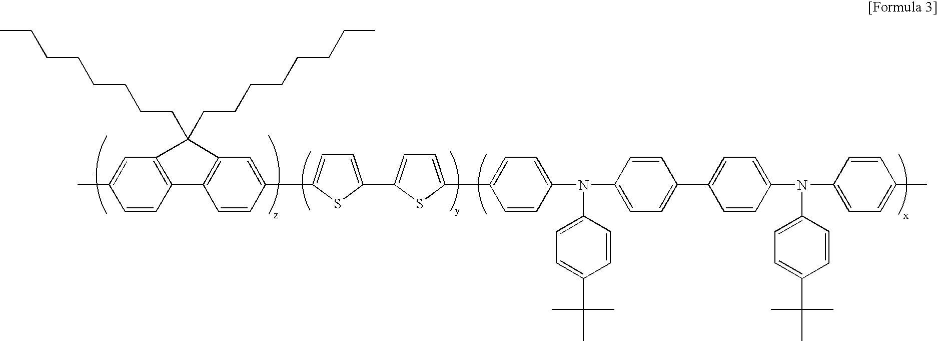

In the formula, x, y, and z indicate constituent ratio, and satisfy 0.1=<x=<0.9, 0.1=<y=<0.9, 0=<z=<0.9, x+y+z=1.

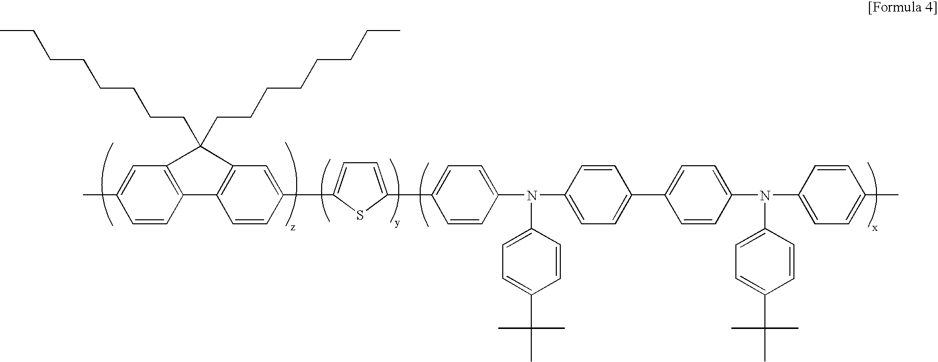

In the formula, x, y, and z indicate constituent ratio, and satisfy 0.1=<x=<0.9, 0.1=<y=<0.9, 0=<z=<0.9, x+y+z=1.

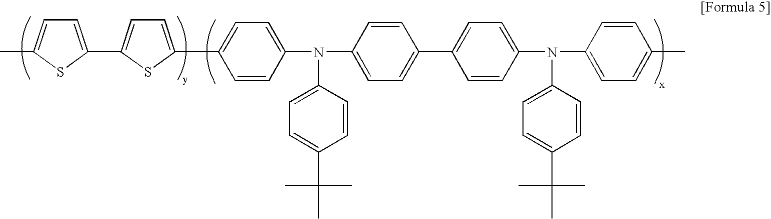

In the formula, x, and y indicate constituent ratio, and satisfy 0.1=<x=<0.9, 0.1=<y=<0.9, x+y=1.

The organic thin film according to the present invention may be formed by adding n-type material to the organic material (p-type polymer material) of the present invention described above. The mixture ratio of p-type polymer material and n-type material is preferably in the range of 1:10 to 10:1 by weight.

As a n-type material, fullerene, fullerene derivative, and perylene derivative, such as, 3,4,9,10-perylenetetracarboxybisbenzimidazole, may be considered.

The manufacturing method according to the present invention is capable of manufacturing the organic photovoltaic cell of the present invention described above, and consists of the steps of adjusting a solution by dissolving an organic material into an organic solvent, and forming an organic thin film from the solution.

According to the present invention, an organic thin film may be formed by application of a solution, a spray method, a printing method and so on, thereby an organic photovoltaic cell may be manufactured in a low cost.

The manufacturing method is favorable in the aspect of environmental health because the solution for the organic material can be adjusted using organic solvents with low environmental load and high safety which does not contain halogen, sulfur, or nitrogen. The organic solvent consists only of carbon and hydrogen, such as xylene and toluene, either of which can be considered as the organic solvent to be used.

According to the present invention, the organic photovoltaic cell can be high in photoelectric conversion efficiency, and can be manufactured by using an organic solvent with a low environmental load and a high safety, such as xylene.

### BRIEF DESCRIPTION OF THE DRAWINGS

FIG. 1 is an outline cross section showing an embodiment of an organic photovoltaic cell according to the present invention.

FIG. 2 shows voltage-current density characteristics of embodiment 1.

FIG. 3 shows wavelength dependence of photoelectric current for embodiment 1.

FIG. 4 shows voltage-current density characteristics of embodiment 2.

FIG. 5 shows wavelength dependence of photoelectric current for embodiment 2.

FIG. 6 shows voltage-current density characteristics of embodiment 3.

FIG. 7 shows wavelength dependence of photoelectric current for embodiment 3.

FIG. 8 shows voltage-current density characteristics of embodiment 4.

FIG. 9 shows wavelength dependence of photoelectric current for embodiment 4.

FIG. 10 shows voltage-current density characteristics of embodiment 5.

FIG. 11 shows wavelength dependence of photoelectric current for embodiment 5.

FIG. 12 shows voltage-current density characteristics of embodiment 6.

FIG. 13 shows voltage-current density characteristics of embodiment 7.

### DETAILED DESCRIPTION OF INVENTION

The present invention is hereinafter explained in detail according to specific embodiments, however, the present invention is not limited to this.

Synthesis of embodiment 1: Synthesis of a p-type polymer material:

Poly[(9,9-dioctylfluorene-2,7-diyl)-co-(bitiophen-2,5′-diyl)-co-[N,N′-bis[4-(1,1-dimethylethyl)phenyl]-benzidine-N,N′-diphenylene-1,4-diyl]]
(PF8-T2 (50%)-TPD (25%)) (compound 1) (JL157)

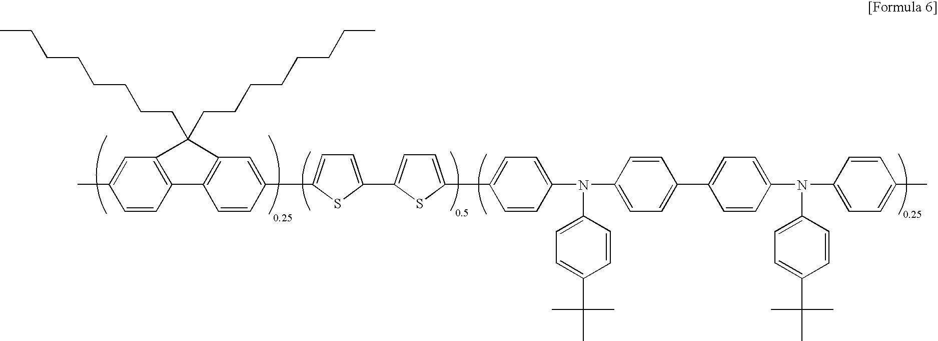

In a dry airtight reaction chamber provided with a mechanical agitator and connectable to a nitrogen line and a vacuum line, add the following substances (1) to (5) for reaction.

(1) N,N′-bis(4-tertbuthylphenyl)-N,N′-bis{4-(4,4,5,5-tetramethyl-1,3,2-dioxaborane)phenyl}benzidine (213 mg, 0.25 mmol)

(2) 9,9-dioctylfluorene-2,7-bis(4,4,5,5-tetramethyl-1,3,2-dioxaborane) (160.5 mg, 0.25 mmol)

(3) 2,5′-dibromo-bitiophen (162 mg, 0.5 mmol)

(4) Toluene solution of Suzuki coupling solvent 5 ml

(5) Base solution 8 ml

The temperature of reaction chamber is increased to 95 degree/C after repeating three times a decompression-nitrogen substitution operation. The reaction is performed for three hours under a nitrogen atmosphere while maintaining the temperature at 95 degree/C. Next, add 61 mg of phenylboronic acid and continue the reaction for two. more hours at 95 degree/C. Thereafter, add approximately 0.12 ml of bromobenzene and continue the reaction for two more hours at 95 degree/C.

Next, cool the product and drop into 300 ml of methanol to precipitate the product.

Next, cleanse this with methanol for three times. After vacuum drying, dissolve the product in 10 ml of toluene and purify with a column chromatography filled with silica gel. After removing the solvent with a rotary evaporator and concentrating down to an adequate amount, drop into 300 ml of methanol to precipitate the product. Cleanse the precipitate three times with methanol, then vacuum dry. Ultimately, brown powder is obtained. The synthetic yield is 90%, the number average molecular weight (Mn) is 1.2×10⁴, weight-average molecular weight (Mw) is 3.5×10⁴, and Mw/Mn is 2.9.

Synthesis of embodiment 2: Synthesis of a p-type polymer material:

Poly[(9,9-dioctylfluorene-2,7-diyl)-co-(thiophene-2,5-diyl)-co-[N,N′-bis[4-(1,1-dimethylethyl)phenyl]-benzidine-N,N′-diphenylene-1,4-diyl]]
(PF8-T (50%)-TPD 25%)) [compound 2] (JL152)

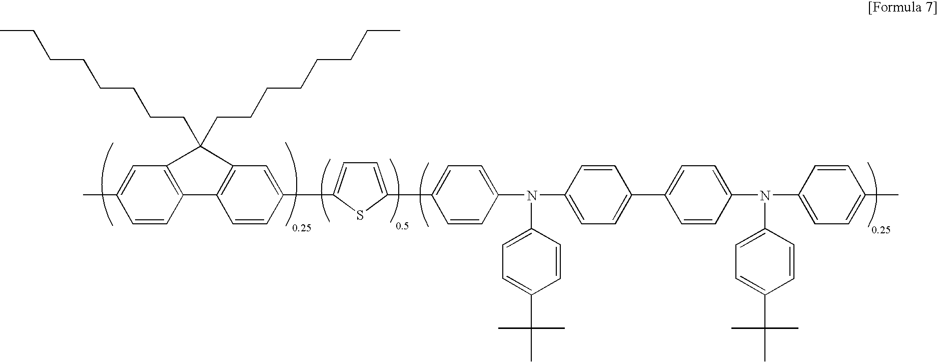

In a dry airtight reaction chamber provided with a mechanical agitator and connectable to a nitrogen line and a vacuum line, add the following substances (1) to (5) for reaction.

(1) N,N′-bis(4-tertbutylphenyl)-N,N5-bis{4-(4,4,5,5-tetramethyl-1,3,2-dioxaborane)phenyl}benzidine (213 mg, 0.25 mmol)

(2) 9,9-dioctylfluorene-2,7-bis(4,4,5,5-tetramethyl-1,3,2, dioxaborane) (160.5 mg, 0.25 mmol)

(3) 2,5′-diiodo-thiophene (168 mg, 0.5 mmol)

(4) Toluene solution of Suzuki coupling solvent 5 ml

(5) Base solution 8 ml

The temperature of the reaction chamber is increased to 95 degree/C after repeating three times a decompression-nitrogen substitution operation. The reaction is performed for three hours under nitrogen atmosphere while maintaining the temperature at 95 degree/C. Next, add 61 mg of phenylboronic acid and continue the reaction for two more hours at 95 degree/C. Thereafter, add approximately 0.12 ml of bromobenzene and continue the reaction for two more hours at 95 degree/C.

Next, cool the product and drop into 300 ml of methanol to precipitate the product.

Next, cleanse this with methanol for three times. After vacuum drying, dissolve the product in 10 ml of toluene and purify with a column chromatography filled with silica gel. After removing the solvent with a rotary evaporator and concentrating down to an adequate amount, drop into 300 ml of methanol to precipitate the product. Cleanse the precipitate three times with methanol, then vacuum dry. Ultimately, a yellow fiber is obtained. The synthetic yield is 90%, the number average molecular weight (Mn) is 3.2×10⁴, weight-average molecular weight (Mw) is 7.5×10⁴, and Mw/Mn is 2.34.

Synthesis of embodiment 3: Synthesis of a p-type polymer material:

Poly[(bithiophene-2,5′-diyl)-co-[N,N′-bis[4-(1,1-dimethylethyl)phenyl]-benzidine-N,N′-diphenylene-1,4-diyl]]
(T2 (50%)-TPD (50%)) [compound 3] (JL237)

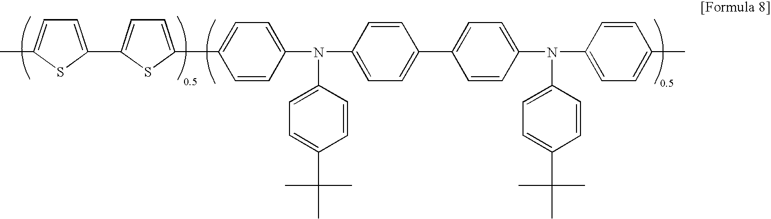

In a dry airtight reaction chamber provided with a mechanical agitator and connectable to a nitrogen line and a vacuum line, add the following substances (1) to (4) for reaction.

(1) N,N′-bis(4-tertbuthylphenyl)-N,N′-bis{4-(4,4,5,5-tetramethyl-1,3,2-dioxaborane)phenyl}benzidine (426 mg, 05 mmol)

(2) 2,5′-dibromo-thiophene (162 mg, 0.5 mmol)

(3) Toluene solution of Suzuki coupling solvent 5 ml

(4) Base solution 8 ml

The temperature of the reaction chamber increased to 95 degree/C after repeating three times a decompression-nitrogen substitution operation. The reaction is performed for three hours under nitrogen atmosphere while maintaining the temperature at 95 degree/C. Next, add 61 mg of phenylboronic acid and continue the reaction for two more hours at 95 degree/C. Thereafter, add approximately 0.12 ml of bromobenzene and continue the reaction for two more hours at 95 degree/C.

Next, cool the product and drop into 300 ml of methanol to precipitate the product.

Next, cleanse this with methanol for three times. After vacuum drying, dissolve the product in 10 ml of toluene and purify with a column chromatography filled with silica gel. After removing the solvent with a rotary evaporator and concentrating down to an adequate amount, drop into 300 ml of methanol to precipitate the product. Cleanse the precipitate three times with methanol, then vacuum dry. Ultimately, brown powder is obtained. The synthetic yield is 84%, the number average molecular weight (Mn) is 1.8×10⁴, weight-average molecular weight (Mw) is 5.3×10⁴, and Mw/Mn is 2.94.

Synthesis of embodiment 4: Synthesis of a p-type polymer material:

Poly[(9,9-dioctylfluorene-2,7-diyl)-alt-(benzothiadiazole-4,7-diyl)]
(PF8-BT) [compound 4] (JL85)

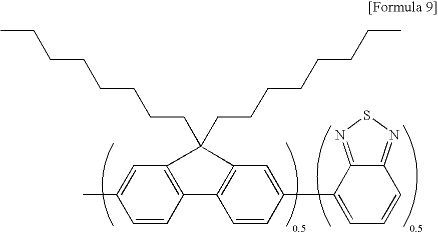

In a dry airtight reaction chamber provided with a mechanical agitator and connectable to a nitrogen line and a vacuum line, add the following substances (1) to (4) for reaction.

(1) 4,7-dibromo benzothiadiazole (147 mg, 0.5 mol)

(2) 9,9-dioethylfluorene-2,7-bis(4,4,5,5-tetramethyl-1,3,2-dioxaborane) (321 mg, 0.5 mmol)

(3) Toluene solution of Suzuki coupling solvent 5 ml

(4) Base solution 8 ml

The temperature of the reaction chamber is increased to 90 degree/C after repeating three times a decompression-nitrogen substitution operation. The reaction is performed for three hours under nitrogen atmosphere while maintaining the temperature at 90 degree/C. Next, add 61 mg of phenylboronic acid and continue the reaction for two more hours at 90 degree/C. Thereafter, add approximately 0.12 ml of bromobenzene and continue the reaction for two more hours at 90 degree/C.

Next, cool the product and drop into 300 ml of methanol to precipitate the product.

Next, cleanse this with methanol for three times. After vacuum drying, dissolve the product in 10 ml of toluene and purify with a column chromatography filled with silica gel. After removing the solvent with a rotary evaporator and concentrating down to an adequate amount, drop into 300 ml of methanol to precipitate the product. Cleanse the precipitate three times with methanol, then vacuum dry. Ultimately, yellow fiber is obtained. The synthetic yield is 90%, the number average molecular weight (Mn) is 6.2×10⁴, weight-average molecular weight (Mw) is 1.9×10⁴, and Mw/Mn is 3.2.

Manufacture and evaluation of an organic photovoltaic cell:

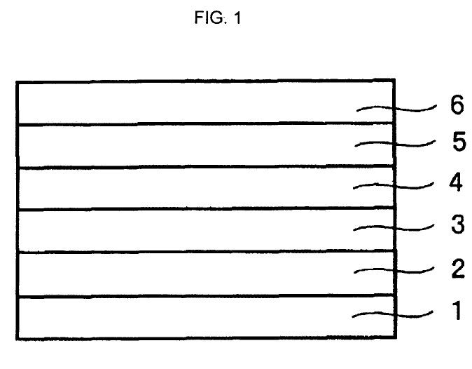

FIG. 1 is an outline cross section showing an organic photovoltaic cell fabricated in each embodiment below. Referring to FIG. 1, an anode 2 consists of indium tin oxide (ITO) and is formed on a glass substrate 1. The anode 2 is patterned, and its area may be 4 mm². Cleanse the glass substrate 1 with the anode 2 using ion-exchange water, 2-propanol and acetone in series, thereafter its surface may be processed with ozone gas by emitting UV rays. A hole transport layer 3 is formed on the anode 2. The hole transport layer 3 is formed by spin coating PEDOT:PSS. The PEDOT:PSS film may be controlled to the thickness of approximately 50 nm, and it may be formed by baking at approximately 200 degree/C for approximately 10 minutes in air after spin coating, then, baking at 80 degree/C for approximately 30 minutes under reduced pressure.

A p-type polymer layer 4 consists of an organic material according to one embodiment of the present invention, and is formed on the hole transport layer 3. The p-type polymer layer 4 is formed by spin coating the solution of p-type polymer on the hole transport layer 3. The p-type polymer solution may be adjusted by using xylene as a solvent. In addition, n-type material may be blend into the p-type polymer layer 4.

An electron transport layer 5 is formed on the p-type polymer layer 4. The electron transport layer 5 is formed by accumulating fullerene (C60) or PV under a vacuum.

A cathode 6 is formed on the electron transport layer 5. The cathode 6 is formed by accumulating aluminum (Al) or silver (Ag). This accumulation is preferably performed under a vacuum.

PEDOT: PSS is a mixture of poly(p-styrenesulfonic acid) salt of poly (3,4-ethylenedioxyphen) and poly(p-styrenesulfonic acid), and has the following structure.

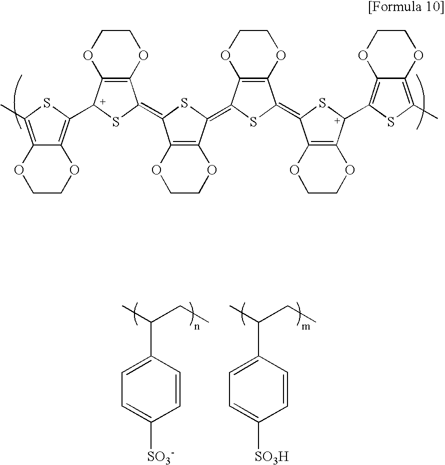

PV is 3,4,9,10-perylenetetracarbonyl-bis-benzimidazole, and has following structure. 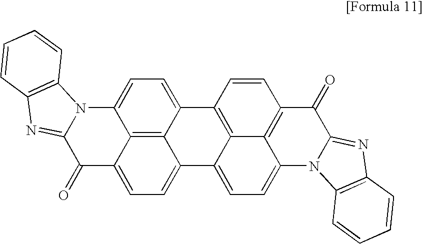
3, 4, 9,10-perylenetetracarboxy-bis-benzimidazole (PV)

### EMBODIMENT 1

The organic photovoltaic cell shown in FIG. 1 is fabricated by using a compound 1 (JL157) as a p-type polymer. An electron transport layer is formed from fullerene (C60), and a cathode is formed from Al. The organic photovoltaic cell according to this embodiment has the following layer structure. The numbers in (parenthesis) indicate film thickness.

ITO/PEDOT (50 nm)/JL157 (30 nm)/C60 (50 nm)/Al (80 nm)

The photoelectric conversion characteristics were evaluated by emitting light of approximately 100 mW/cm² of irradiation intensity, spectrum AM (Air Mass) 1.5 on the organic photovoltaic cell obtained.

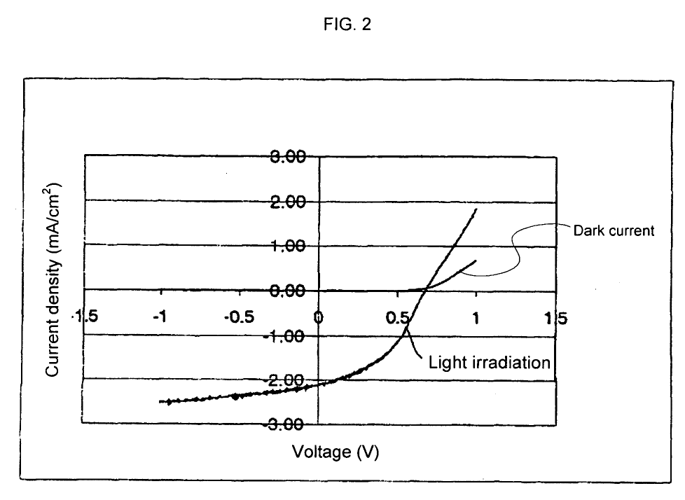

FIG. 2 shows voltage-current density characteristics. In the figure, the upper curve indicates the characteristics of dark current, and the lower curve indicates the characteristics at light irradiation.

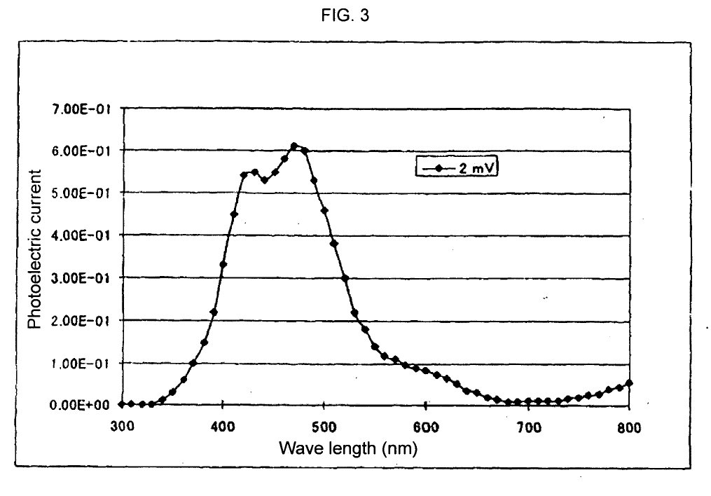

FIG. 3 show the wavelength dependence of photoelectric current.

Short circuit current (Isc), open voltage (Voc), fill factor (ff), and photoelectric conversion efficiency of the organic photovoltaic cell for this embodiment are shown in table 1.

### EMBODIMENT 2

The organic photovoltaic cell shown in FIG. 1 is fabricated by using a compound 1 (JL157) as a p-type polymer. An electron transport layer is formed from PV, and a cathode is formed from Ag. The organic photovoltaic cell according to this embodiment has the following layer structure.

ITO/PEDOT (50 nm)/JL157 (30 nm)/PV (30 nm)/Ag (50 nm)

The photoelectric conversion characteristics were evaluated by emitting light of approximately 100 mW/cm² of irradiation intensity, spectrum AM (Air Mass) 1.5 on the organic photovoltaic cell obtained.

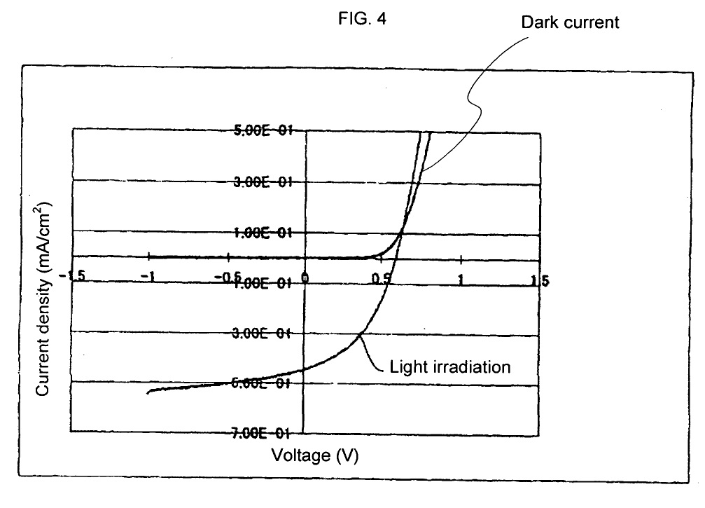

FIG. 4 shows voltage-current density characteristics. In the figure, the upper curve indicates the characteristics of dark current, and the lower curve indicates the characteristics at light irradiation.

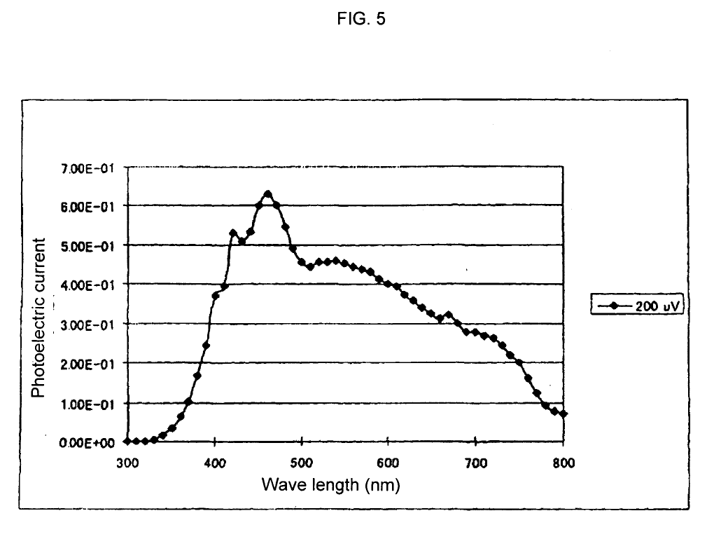

FIG. 5 shows the wavelength dependence of photoelectric current.

Short circuit current (Isc), open voltage (Voc), fill factor (ff), and photoelectric conversion efficiency of the organic photovoltaic cell for this embodiment are shown in table 1.

### EMBODIMENT 3

The organic photovoltaic cell shown in FIG. 1 is fabricated by using a compound 1 (JL157) as a p-type polymer, blending with PCBM of n-type material in 1:3 by weight, and forming a p-type polymer layer. An electron transport layer is formed from PV, and a cathode is formed from Ag. The organic photovoltaic cell according to this embodiment has the following layer structure.

ITO/PEDOT (50 nm)/JL157:PCBM (1:3)(50 nm)/PV(30 nm)/Ag (50 nm) PCBM has the following structure.

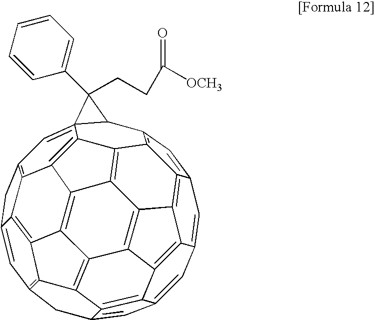

The photoelectric conversion characteristics were evaluated by emitting light of approximately 100 mW/cm² of irradiation intensity, spectrum AM (Air Mass) 1.5 on the organic photovoltaic cell obtained.

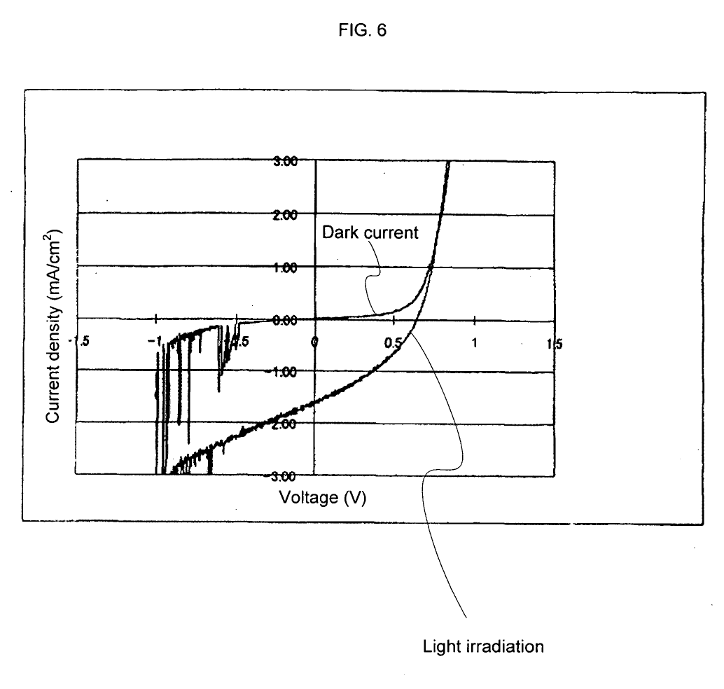

FIG. 6 shows voltage-current density characteristics. In the figure, the upper curve indicates the characteristics of dark current, and the lower curve indicates the characteristics at light irradiation.

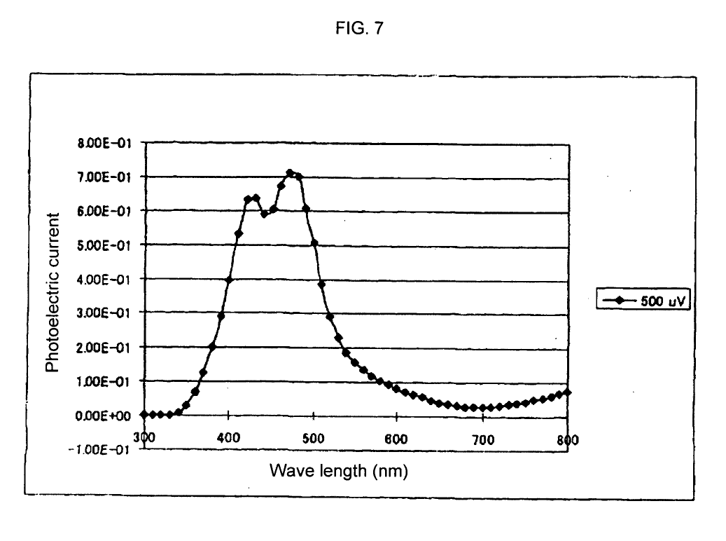

FIG. 7 shows the wavelength dependence of photoelectric current.

Short circuit current (Isc), open voltage (Voc), fill factor (ff), and photoelectric conversion efficiency of the organic photovoltaic cell for this embodiment are shown in table 1.

### EMBODIMENT 4

The organic photovoltaic cell shown in FIG. 1 is fabricated by using a compound 1 (JL157) as a p-type polymer, blending with PCBM of n-type material in 1:3 by weight, and forming a p-type polymer layer. An electron transport layer is formed from fullerene (C60), and a cathode is formed from Al. The organic photovoltaic cell according to this embodiment has the following layer structure.

ITO/PEDOT (50 nm)/JL157:PCBM (1:3) (35 nm)/C60 (50 nm)/Al (80 nm) The photoelectric conversion characteristics were evaluated by emitting a light 100 mW/cm² of irradiation intensity, spectrum AM (Air Mass) 1.5 on the organic photovoltaic cell obtained.

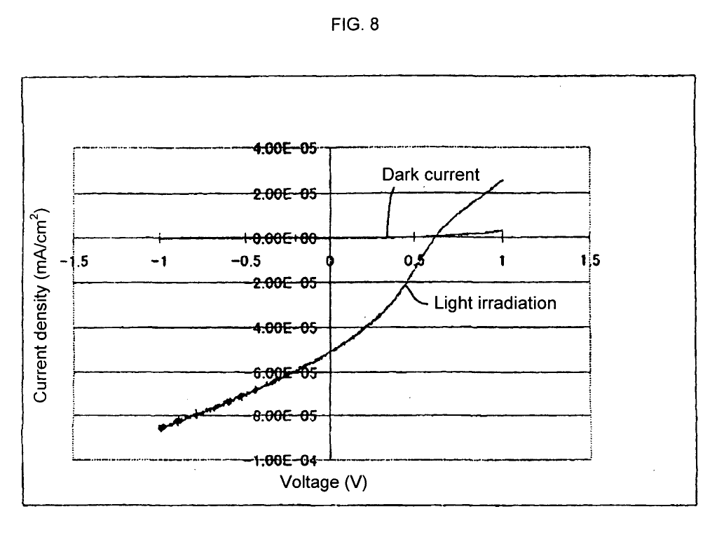

FIG. 8 shows voltage-current density characteristics. In the figure, the upper curve indicates the characteristics of dark current, and the lower curve indicates the characteristics at light irradiation.

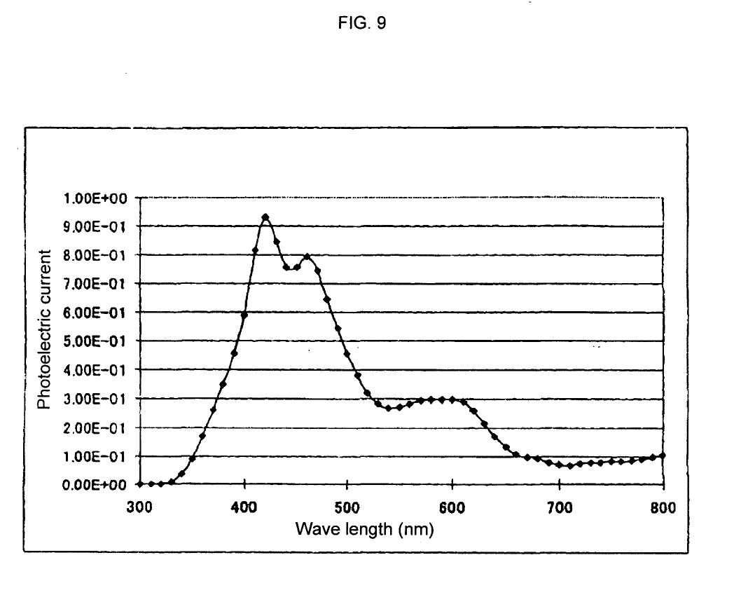

FIG. 9 shows the wavelength dependence of photoelectric current.

Short circuit current (Isc), open voltage (Voc), fill factor (ft, and photoelectric conversion efficiency of the organic photovoltaic cell for this embodiment are shown in table 1.

### EMBODIMENT 5

The organic photovoltaic cell shown in FIG. 1 is fabricated by using a compound 1 (JL157) as a n-type polymer, blending with compound 4 (JL85) of n-type material in 1:1 by weight, and forming a p-type polymer layer. An electron transport layer is formed from fullerene (C60), and a cathode is formed from Al. The organic photovoltaic cell according to this embodiment has the following layer structure.

ITO/PEDOT (50 nm)/JL157:JL85 (1:1) (40 nm)/C60 (50 nm)/Al (80 nm) The photoelectric conversion characteristics were evaluated by emitting a light 100 mW/cm² of irradiation intensity, spectrum AM (Air Mass) 1.5 on the organic photovoltaic cell obtained.

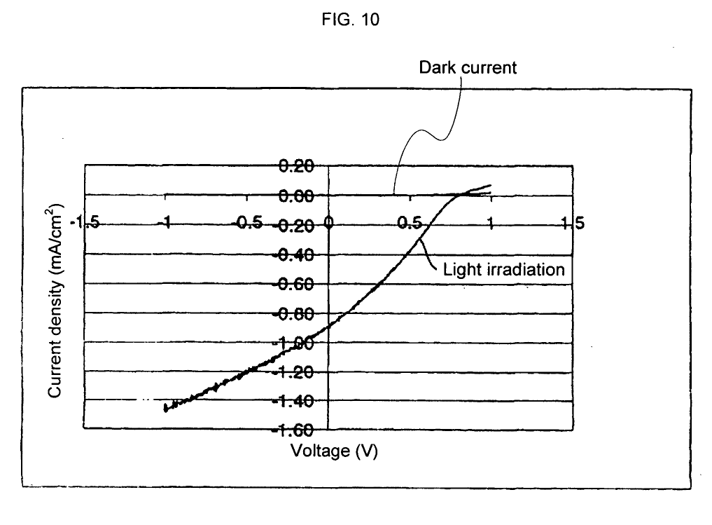

FIG. 10 shows voltage-current density characteristics. In the figure, the upper curve indicates the characteristics of dark current, and the lower curve indicates the characteristics at light irradiation.

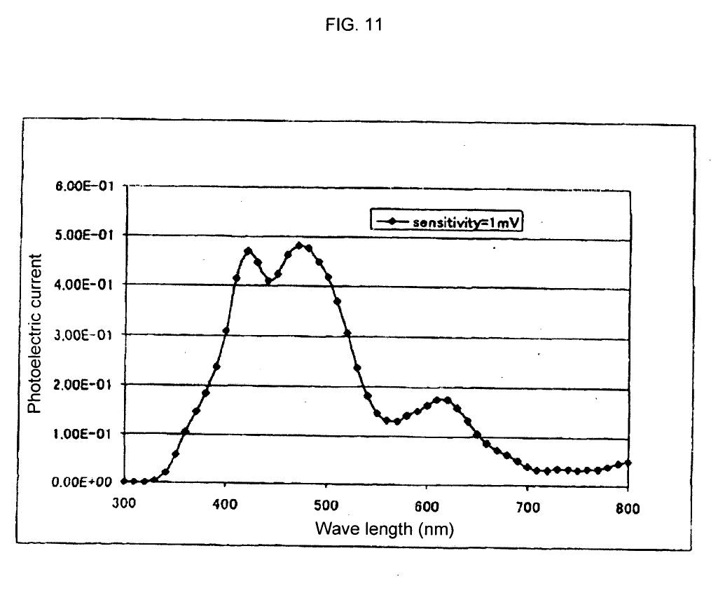

FIG. 11 shows the wavelength dependence of photoelectric current.

Short circuit current (Isc), open voltage (Voc), fill factor (ff), and photoelectric conversion efficiency of the organic photovoltaic cell for this embodiment are shown in table 1.

### EMBODIMENT 6

The organic photovoltaic cell shown in FIG. 1 is fabricated by using a compound 2 (JL152) as a p-type polymer. An electron transport layer is formed from fullerene (C60), and a cathode is formed from Al. The organic photovoltaic cell according to this embodiment has the following layer structure.

ITO/PEDOT (50 nm)/JL152 (50 nm)/C60 (50 nm)/Al (80 nm)

The photoelectric conversion characteristics were evaluated by emitting a light 100 mW/cm² of irradiation intensity, spectrum AM (Air Mass) 1.5 on the organic photovoltaic cell obtained.

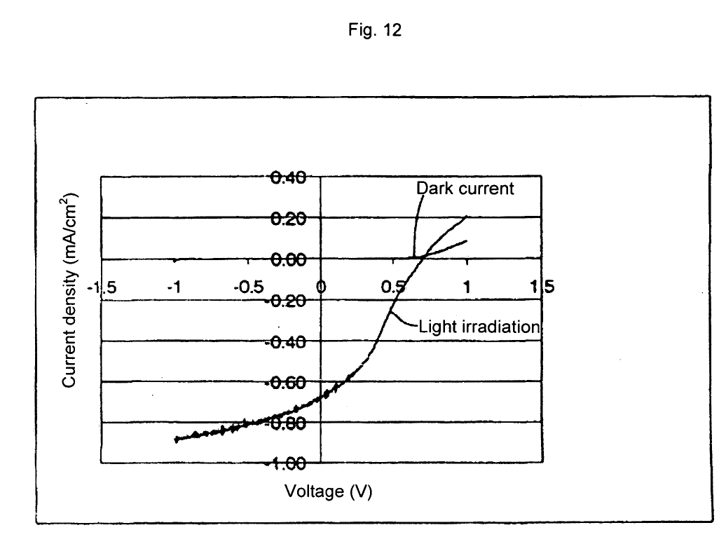

FIG. 12 shows voltage-current density characteristics. In the figure, the upper curve indicates the characteristics of dark current, and the lower curve indicates the characteristics at light irradiation.

Short circuit current (Isc), open voltage (Voc), fill factor (ff), and photoelectric conversion efficiency of the organic photovoltaic cell for this embodiment are shown in table 1.

### EMBODIMENT 7

As a p-type polymer, the organic photovoltaic cell shown in FIG. 1 is fabricated using a compound 3 (JL237). An electron transport layer is formed from PV, and a cathode is formed from Ag. The organic photovoltaic cell according to this embodiment has the following layer structure.

ITO/PEDOT (50 nm)/JL237 (40 nm)/PV (30 nm)/Ag (50 nm) The photoelectric conversion characteristics were evaluated by emitting a light 100 mW/cm² of irradiation intensity, spectrum AM (Air Mass) 1.5 on the obtained organic photovoltaic cell.

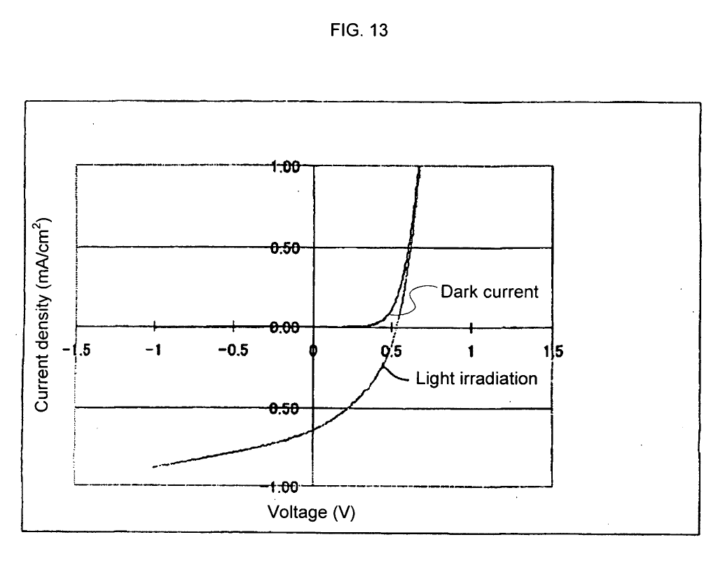

FIG. 13 shows voltage-current density characteristics. In the figure, the upper curve indicates the characteristics of dark current, and the lower curve indicates the characteristics at light irradiation.

Short circuit current (Isc), open voltage (Voc), fill factor (ff), and photoelectric conversion efficiency of the organic photovoltaic cell for this embodiment are shown in table 1.

TABLE 1

| | | | | Conversion |
|---|---|---|---|---|
| | Isc (mA/cm²) | Voc (V) | ff | efficiency (%) |
| Embodiment 1 | 2.14 | 0.67 | 0.43 | 0.644 |
| Embodiment 2 | 0.441 | 0.59 | 0.44 | 0.114 |
| Embodiment 3 | 1.60 | 0.64 | 0.347 | 0.374 |
| Embodiment 4 | 1.35 | 0.63 | 0.3 | 0.27 |
| Embodiment 5 | 0.902 | 0.80 | 0.28 | 0.21 |
| Embodiment 6 | 0.685 | 0.70 | 0.3 | 0.151 |
| Embodiment 7 | 0.644 | 0.54 | 0.39 | 0.135 |

It is evident from the above results that the organic photovoltaic cell according to the present invention indicates favorable photoelectric conversion characteristics. Also, the p-type polymer layer may be formed by using an organic solvent with a small environmental load, such as xylene.

In addition, the present invention is not limited to the above embodiments. For example, in the manufacturing method of an organic material according to the present invention, the cleaning solution is not limited to methanol, and for example, ethanol or propanol may be used. Also, the number of cleansings is not limited to three times, it may be any number. For example, it may be once or twice. Also, the operation of decompression-nitrogen substitution is not limited to three times, and it may be any number of times. For example, it may be once or twice. In addition, the reaction may not be performed under a nitrogen atmosphere, it may be, for example, performed under an argon atmosphere. And the purification method is not limited to column chromatography, it may be recrystallization. Further, the solvent to resolve a product when performing the column chromatography is not limited to toluene, it may be hexane or propanol.

What is claimed is:

1. An organic photovoltaic cell comprising a pair of electrodes and an organic thin film provided between the electrodes for photoelectric conversion, wherein said organic thin film is formed from an organic material with a following chemical structure: 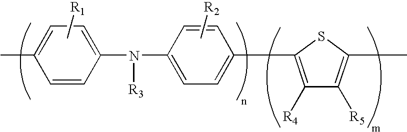
where, R₁-R₅ are selected from at least one of a group consisting of a hydrogen, an alkyl group, an alkoxy group, an aryl group, and include at least one element selected from a group consisting of an oxygen, a nitrogen, a silicon, a phosphorus and a sulfur, and where n and m are counting numbers in a range of 1 to 10000.

2. The organic photovoltaic cell according to claim 1, wherein said organic material has a following chemical structure: 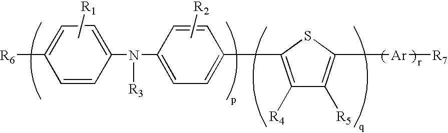
where Ar is an aryl group, R₁-R₇ are selected from at least one of a group consisting of a hydrogen, an alkyl group, an alkoxy group, and a aryl group, and include at least one element selected from a group consisting of an oxygen, a nitrogen, a silicon, a phosphorus, and a sulfur, and where p is a counting number in a range of 1 to 10000, q is a counting number in a range of 1 to 20000, and r is an integral number in a range of 0 to 10000.

3. The organic photovoltaic cell according to claim 2, wherein said organic material has a following chemical structure: 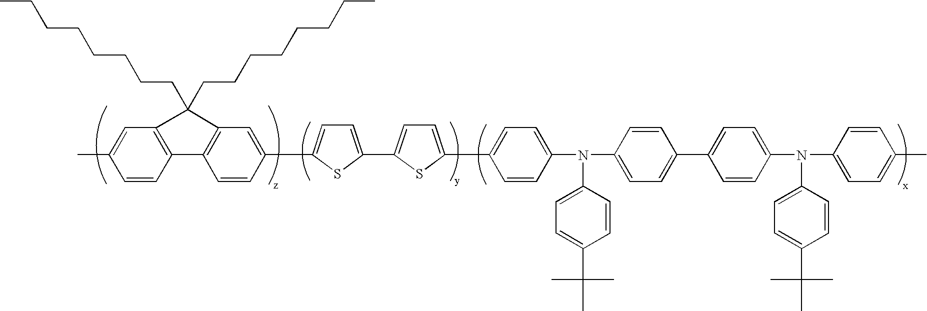
where x, y, and z indicate a constituent ratio, and satisfy 0.1=<x=<0.9, 0.1=<y=<0.9, 0=<z=<0.9, x+y+z=1.

4. The organic photovoltaic cell according to claim 2, wherein said organic material has a following chemical structure: 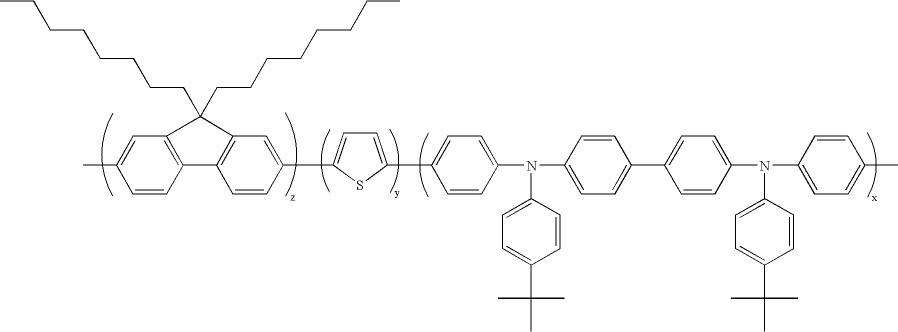
where x, y, and z indicate a constituent ratio, and satisfy 0.1=<x=<0.9, 0.1=<y=<0.9, 0=<z=<0.9, x+y+z=1.

5. The organic photovoltaic cell according to claim 2, wherein said organic material has a following chemical structure: 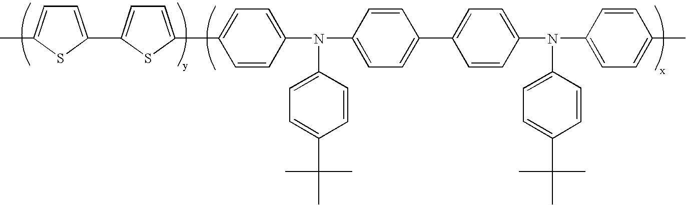
where x and y indicate a constituent ratio, and satisfy 0.1=<x=<0.9, 0.1=<y=<0.9, x+y=1.

6. An organic material for manufacturing an organic thin film, wherein the organic material has a structure indicated by a following formula: 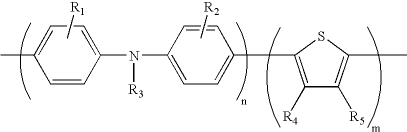
where R₁-R₅ are selected from at least one of a group consisting of a hydrogen, an alkyl group, an alkoxy group, and a aryl group, and include at least one element selected from a group consisting of an oxygen, a nitrogen, a silicon, a phosphorus and a sulfur, where n and m are counting numbers in a range of 1 to 10000.

7. The organic material according to claim 6, wherein said organic material has a structure indicated by a following formula: 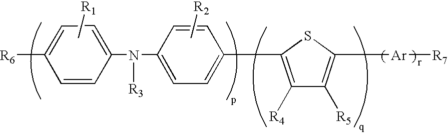
where Ar is an aryl group, and R₁-R₇ are selected from at least one of a group consisting of a hydrogen, an alkyl group, an alkoxy group, and a aryl group, and include at least one element selected from a group consisting of an oxygen, a nitrogen, a silicon, a phosphorus or a sulfur, where p is a counting number in a range of 1 to 10000, q is a counting number in a range of 1 to 20000, and r is an integral number in a range of 0 to 10000)

8. The organic material according to claim 7, wherein said organic material has a structure indicated by a following formula: 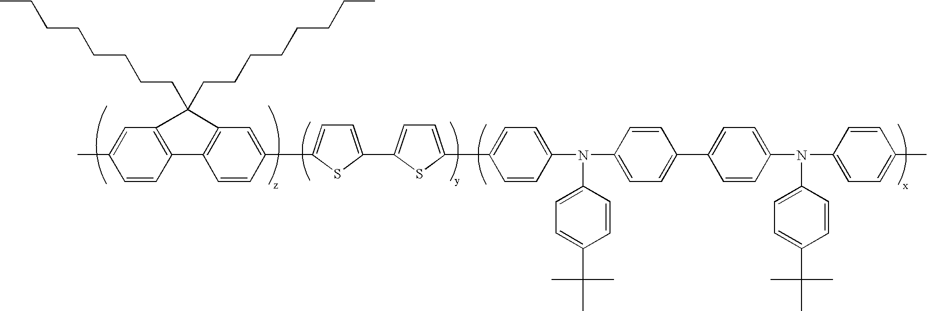
where x, y, and z indicate a constituent ratio, and satisfy 0.1=<x=<0.9, 0.1=<y=<0.9, 0=<z=<0.9, x+y+z=1.

9. The organic material according to claim 7, wherein said organic material has a structure indicated by a following formula: 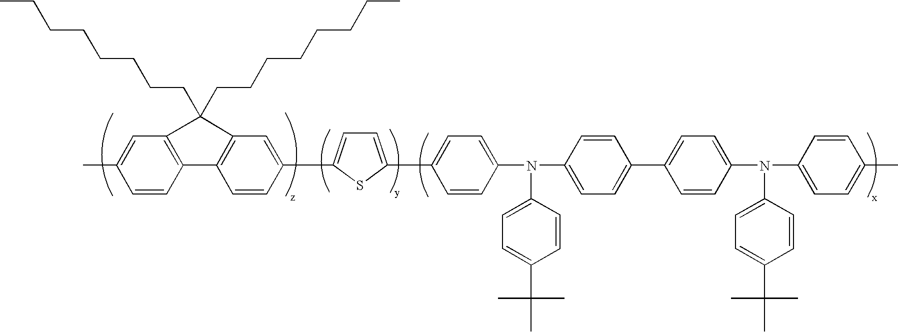
where x, y, and z indicate a constituent ratio, and satisfy 0.1=<x=<0.9, 0.1=<y=<0.9, 0=<z=<0.9, x+y+z=1.

10. The organic material according to claim 7, wherein said organic material has a structure indicated by a following formula: 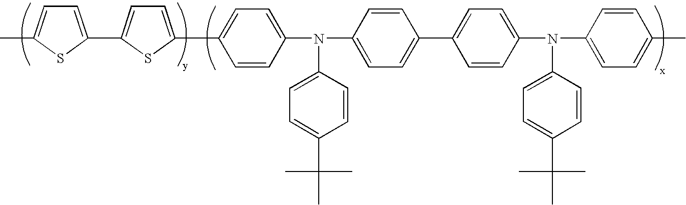
where x and y indicate a constituent ratio, and satisfy 0.1=<x=<0.9, 0.1=<y=<0.9, x+y=1.

11. A method for manufacturing an organic photovoltaic cell, the method comprising the steps of:
adjusting a solution by dissolving said organic material into an organic solvent, the material having a chemical structure of: 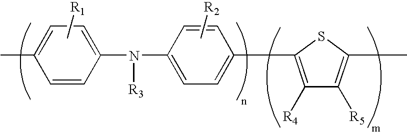
where, R₁-R₅ are selected from at least one of a group consisting of a hydrogen, an alkyl group, an alkoxy group, an aryl group, and include at least one element selected from a group consisting of an oxygen, a nitrogen, a silicon, a phosphorus and a sulfur, and where n and m are counting numbers in a range of 1 to 10000; and
forming an organic thin film from said solution.

12. The manufacturing method of claim 11, wherein said organic solvent is xylene or toluene.
